(19) United States
(12) Patent Application Publication
(10) Pub. No.: US 2025/0004079 A1
(43) Pub. Date: Jan. 2, 2025

(54) MAGNETIC RESONANCE IMAGING DEVICE AND METHOD FOR ACQUIRING A MAGNETIC RESONANCE IMAGE

(71) Applicant: Multiwave Technologies, Marseille cedex 13 (FR)

(72) Inventors: Marc Dubois, Marseille cedex 13 (FR); Gianfranco Andia Vera, Marseille cedex 13 (FR); Mathieu Cosker, Marseille cedex 13 (FR); Tryfon Antonakakis, Marseille cedex 13 (FR)

(21) Appl. No.: 18/705,281

(22) PCT Filed: Oct. 21, 2022
(86) PCT No.: PCT/FR2022/052002

§ 371 Date: Apr. 26, 2024

(30) Foreign Application Priority Data
Oct. 28, 2021 (FR) FR2111501

(51) Int. Cl. G01R 33/36; G01R 33/383; G01R 33/385; G01R 33/561

(52) U.S. Cl. CPC G01R 33/3628; G01R 33/383; G01R 33/385; G01R 33/5615

(57) ABSTRACT

A magnetic resonance imaging device includes a radio frequency assembly configured to transmit and receive radio frequency signals, the radio frequency assembly comprising: a radio frequency coil, which is characterized for an intrinsic bandwidth and an intrinsic resonant frequency and intended for transmitting and receiving radio frequency signals; a tunable circuit, which is associated with the radio frequency coil and configured to make it possible to adjust the equivalent impedance of the radio frequency assembly within a given impedance range, the adjustment of the equivalent impedance making it possible to adjust the resonant frequency, referred to as the adjusted frequency, and the bandwidth, referred to as the adjusted band, of the radio frequency assembly, the adjusted frequency and the adjusted band each being included in the intrinsic bandwidth so that the radio frequency assembly has a higher quality factor than the quality factor of the radio frequency coil alone.

### CROSS-REFERENCE TO RELATED APPLICATIONS

This application is a national phase entry under 35 U.S.C. § 371 of International Patent Application PCT/FR2022/052002, filed Oct. 21, 2022, designating the United States of America and published as International Patent Publication WO 2023/073311 A1 on May 4, 2023, which claims the benefit under Article 8 of the Patent Cooperation Treaty of French Patent Application Serial No. 2111501, filed Oct. 28, 2021.

### TECHNICAL FIELD

The present disclosure relates to the field of magnetic resonance imaging. More particularly, the present disclosure relates to a magnetic resonance imaging apparatus, and, in particular, a magnetic resonance imaging apparatus provided with a radio frequency assembly equipped with a transmitting/receiving radio frequency coil. More particularly, the radio frequency assembly according to the present disclosure is also provided with a radio frequency coil, which has a narrow bandwidth and means for adjusting the resonant frequency of the radio frequency assembly in a range of working frequencies that extends further than the bandwidth of the coil. The arrangement thus proposed makes it possible to improve the quality of the images when a relatively small static magnetic field must be considered.

### BACKGROUND

The present disclosure is particularly advantageous when considering a portable magnetic resonance imaging device.

Magnetic resonance imaging (MRI) is currently widely used to image, non-invasively, the interior of bodies and, in particular, human bodies. In particular, magnetic resonance imaging makes it possible to probe the hydrogen nuclei, and, in particular, their nuclear spin, of water molecules forming part of the body being examined.

In this respect, an MRI apparatus is provided with a magnet intended to impose on the body a static magnetic field (called “main magnetic field”), under the effect of which the nuclear spins associated with the hydrogen nuclei contained in the water molecules forming part of this body polarize.

In particular, the magnetic moments associated with these spins are preferentially aligned along an axis called the z axis, determined by the orientation of the main magnetic field so as to create a magnetization of the body.

An MRI apparatus also comprises gradient coils configured to produce magnetic fields of small amplitude and varying in space when a current is applied thereto. More particularly, the gradient coils are designed to produce a magnetic field component that is aligned parallel to the main magnetic field, and which varies linearly in amplitude with the position along one of the axes x, y or z (with each pair of axes x, y and z being perpendicular).

Thus, the combined effects of the magnetic fields imposed by the gradient coils make it possible to spatially encode each of the positions of the body intended to be probed.

An MRI apparatus also comprises at least one radiofrequency (RF) coil intended to act as an RF receiver transmitter. In particular, the at least one radio frequency coil is configured to emit RF energy pulses of a frequency equal to or close to the resonant frequency of the hydrogen nuclei spins and which is at least partially absorbed by these nuclei.

As soon as the RF emission is interrupted, the nuclear spins relax in order to return to their initial energy state and in turn emit a RF signal capable of being collected by at least one RF coil. This RF signal is then processed using a computer and reconstruction algorithms in order to obtain an image of the body.

The main magnetic field, generally comprised between 1.5 Tesla and 3 Tesla, makes it possible to achieve relatively reasonable signal-to-noise ratios and consequently to form images of the human body of sufficient quality and over durations on the order of one minute or more.

However, there are circumstances wherein it is not possible to implement a main magnetic field of such an intensity. Portable MRI apparatuses are an example thereof. The latter generally comprise a permanent magnet or electromagnets of limited capacity and cannot impose a main magnetic field with an intensity greater than 60 mT, or even greater than 200 mT, without adversely affecting the mass or bulk of the MRI apparatus considered.

This limitation in terms of main magnetic field intensity directly affects the performance of the MRI apparatus. In particular, the quality of the images obtained with such an MRI device may be heavily degraded by an unfavorable signal-to-noise ratio. This unfavorable signal-to-noise ratio reflects, in part, a significant reduction in the magnetization present in the tissues.

One aim of the present disclosure is to propose a magnetic resonance imaging device, advantageously implementing a main magnetic field of low intensity, provided with a radio frequency assembly making it possible to improve the signal-to-noise ratio and consequently the quality of the images.

### BRIEF SUMMARY

The present disclosure relates to a magnetic resonance imaging device that comprises a radio frequency assembly configured to transmit and receive radio frequency signals, the assembly comprising:
a radio frequency coil, which is characterized for an intrinsic bandwidth and an intrinsic resonant frequency and intended for transmitting and receiving radio frequency signals;
a tunable circuit, which is associated with the radio frequency coil and configured to make it possible to adjust the equivalent impedance of the radio frequency assembly within a given impedance range, the adjustment of the equivalent impedance making it possible to adjust the resonant frequency, referred to as the adjusted frequency, within a frequency range, called the working frequency, of the radio frequency assembly, the extent of the working frequency being greater than the extent of the intrinsic bandwidth;
adjustment means configured to command the tunable circuit to dynamically adjust the equivalent impedance, during the acquisition of an image by the imaging device.

According to one embodiment, the adjustment means are configured to allow a radio frequency transmission at a given frequency, called the Larmor frequency, and a reception of radio frequency signals during which the adjusted frequency is dynamically tuned in the working range.

According to one embodiment, the radio frequency coil comprises capacitors, called main segmentation capacitors.

According to one embodiment, the tunable circuit comprises at least two components arranged according in an L-shaped topology, and which combined together in the tunable circuit generate a reactance, one and/or the other of these two components being tunable so as to allow the adjustment of the equivalent impedance of the radio frequency assembly. Advantageously, the two components comprise two capacitors, or two inductors, or a capacitor and an inductor.

According to one embodiment, the tunable circuit comprises two inputs and two outputs, the two inputs called, respectively, first input and second input, are intended to be powered by a generator of current pulses, while the two outputs called, respectively, the first output and second output, are each connected to one of the ends of the radio frequency coil.

According to one embodiment, the radio frequency assembly comprises two branches, respectively, a first branch and second branch, connected in parallel to the level respectively of the first input and of the second input, the first branch comprising, connected in series, the radio frequency coil and one of the two components, while the second branch comprises the other of the two components.

According to one embodiment, the radio frequency assembly further comprises means for generating radio frequency pulses, the means for generating radio frequency pulses being adapted to impose, via the tunable circuit, the circulation of a current pulse in the radio frequency coil.

According to one embodiment, the imaging device comprises radio frequency processing means, the radio frequency processing means being adapted to process a radio frequency signal capable of being received by the radio frequency coil.

According to one embodiment, the imaging device comprises a magnet defining a bore wherein the radio frequency coil is arranged, the interior of the radio frequency coil forming a zone, called the analysis zone, wherein the magnet imposes a static magnetic field.

According to one embodiment, the magnet is a permanent magnet, advantageously, the permanent magnet is capable of generating a static magnetic field less than 100 mT, even more advantageously less than 50 mT.

According to one embodiment, the device also comprises gradient coils intended to spatially encode each of the positions of the analysis zone, the spatial encoding, in combination with the static magnetic field, being intended to associate with each of the positions a resonant frequency, called the natural frequency, to the spins of hydrogen nuclei likely to be positioned at the position.

According to one embodiment, the adjusted frequency can cover, by adjusting the equivalent impedance, all of the natural frequencies of the hydrogen nuclei spins likely to be present on each of the positions of the analysis zone.

The present disclosure also relates to a method for acquiring an image by magnetic resonance of a body by means of the imaging device of the present disclosure, the method comprising the following steps:
a) subjecting the body, disposed within the radio frequency coil, to the static magnetic field;
b) imposing on the body a spatial encoding by means of the gradient coils, the gradient coils subjecting the body to a gradient field, which adds to the static magnetic field, to form a resultant field, in order to associate with each of the positions of the body a resonant frequency, called the natural frequency, of the spins of the hydrogen nuclei, all of the natural frequencies extending over the working range;
c) transmitting, by means of the radio frequency coil, a radio frequency signal so as to excite, over all positions of the body subjected to spatial encoding by the gradient coils, the hydrogen nuclei spins,
d) measuring the echoes of hydrogen nuclei spins emitted by at least some of the positions of the body subjected to the spatial encoding by the gradient coils, the measurement comprising a dynamic adjustment of the equivalent impedance of the assembly formed by the tunable circuit and the radio frequency coil.

According to one embodiment, the spatial encoding imposed by the gradient coils is reflected by a breakdown, in terms of the resultant field, into slices called working slices, the working slices themselves being subdivided into mutually parallel working lines, along which the resultant field varies.

According to one embodiment, the measurement of the spin echoes is carried out one working line at a time.

According to one embodiment, the spin echoes likely to be measured along a working line cover a frequency range whose extent is greater than the bandwidth of the radio frequency coil, the measurement along a working line is executed by dynamically adjusting the equivalent impedance of the assembly formed by the tunable circuit and the radio frequency coil so as to collect all the spin echoes associated with the working line.

According to one embodiment, the frequency range associated with the spin echoes of one line is of an extent at least 5 times greater, advantageously 10 times greater, than the intrinsic bandwidth of the radio frequency coil.

### BRIEF DESCRIPTION OF THE DRAWINGS

Other features and advantages of the present disclosure will be clear from the detailed description, made in reference to the appended figures, wherein:

FIG. 1 is a schematic representation according to an exploded view of a magnetic resonance imaging device;

FIG. 2 is a schematic representation of a radio frequency assembly according to the present disclosure;

FIG. 3 is a graphic representation of the response of a radio frequency assembly according to the present disclosure, and provided with a radio frequency coil, FIG. 3, in particular, represents the characteristic (i.e.,: reflection coefficient in dB on the vertical axis) of the assembly for different adjustments of the resonant frequency in a working range of 30 kHz (the horizontal axis representing the frequency in MHz), more particularly, FIG. 3 shows four intensity profiles for four different settings (curves “A,” “B,” “C,” and “D”) of the tunable circuit;

FIG. 4 shows a radio frequency assembly whose first branch is formed by a serial connection of the radio frequency coil and of the capacitor C1, and a second branch formed by the inductor L1;

FIG. 5 shows a radio frequency assembly whose first branch is formed by a serial connection of the radio frequency coil and of the inductor L1, and a second branch formed by the capacitor C1;

FIG. 6 shows a radio frequency assembly whose first branch is formed by a serial connection of the radio frequency coil and of a capacitor C2, and a second branch formed by the capacitor C1; and

FIG. 7 shows the effect of the quality factor of the radio frequency coil on the image obtained, the image (1) and the image (2) are obtained by means of an imaging device comprising a radio frequency coil having, respectively, a standard quality factor and a high quality factor (greater than the standard quality factor).

### DETAILED DESCRIPTION

The present disclosure relates to a magnetic resonance imaging device that comprises a radio frequency assembly configured to transmit and receive radio frequency signals.

In particular, the radio frequency assembly comprises a radio frequency coil, which is characterized for an intrinsic bandwidth and an intrinsic resonant frequency and intended for transmitting and receiving radio frequency signals.

The radio frequency assembly also comprises a tunable circuit, which is associated with the radio frequency coil and configured to make it possible to adjust the equivalent impedance of the radio frequency assembly within a given impedance range, the adjustment of the equivalent impedance making it possible to adjust the resonant frequency, referred to as the adjusted frequency, within a frequency range, called the working range, of the radio frequency assembly. In this respect, the extent of the working range is greater than the extent of the intrinsic bandwidth.

The radio frequency assembly further comprises adjustment means configured to command the tunable circuit to dynamically adjust the equivalent impedance, during the acquisition of an image by the imaging device.

The association of the tunable circuit and the adjustment means makes it possible to consider a radio frequency coil, which has a bandwidth of an extent smaller than the working range. This latter consideration more particularly makes it possible to implement a radio frequency coil whose quality factor is greater than that of the coils usually considered and for which it is generally required that they have a bandwidth covering at least the working range. The principles of the present disclosure thus make it possible to improve the quality of the images obtained by the magnetic resonance imaging device, and to envisage the implementation of a main magnetic field of low amplitude, and, in particular, of less than 100 mTesla, or even less than 50 mTesla. According to these conditions relating to the main magnetic field, the quality factor of the radio frequency coil is advantageously between 90 and 120 (the quality factor of the coil being defined as the ratio of the resonant frequency of the coil to its bandwidth).

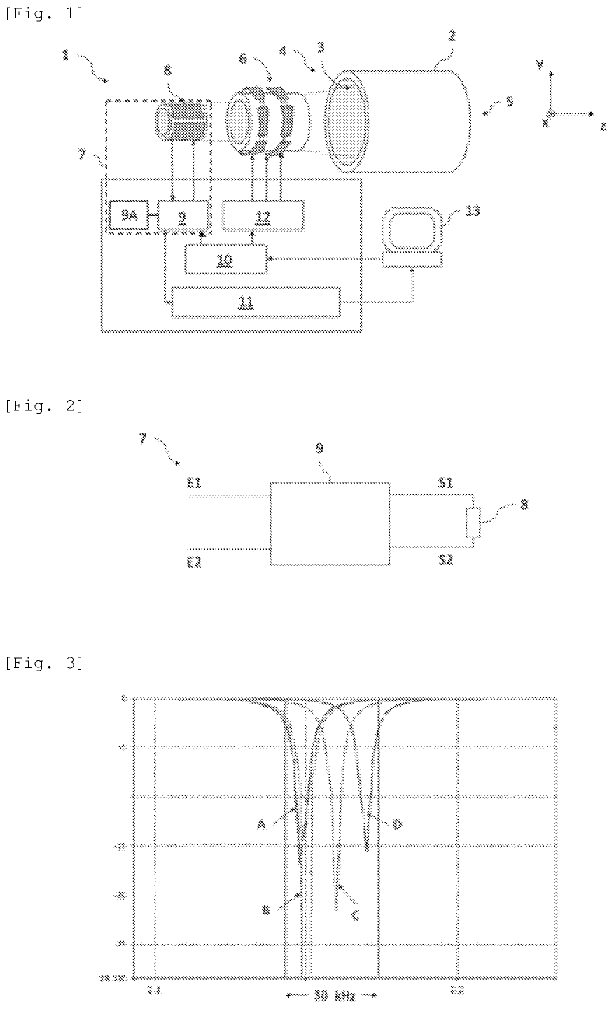

Thus, FIG. 1 is a schematic representation of a magnetic resonance imaging device 1 according to the present disclosure.

The imaging device 1 comprises a magnet, and, in particular, a permanent magnet 2. The permanent magnet 2 may, in particular, extend along an elongation axis z.

More particularly, the permanent magnet 2 defines a bore 3 that opens up through a first opening 4 and a second opening 5 opposite each other along the elongation axis z.

In this respect, the permanent magnet 2 is arranged to allow the insertion of a body, and more particularly of a human body, into the bore 3 through the first opening 4 along the elongation axis z.

The permanent magnet 2 is more particularly configured to impose a static magnetic field oriented along an axis perpendicular to the elongation axis z, in a zone, called the analysis zone, of the bore 3.

In this respect, the permanent magnet 2 may comprise an assembly of elementary magnets, and, in particular, arranged in series of Halbach rings. Document EP3368914B1 gives an example thereof. However, the present disclosure is not limited solely to the configuration described in this document.

By way of example, the permanent magnet 2 is configured to impose a static magnetic field with an amplitude of less than 100 mT, advantageously less than 65 mT, even more advantageously less than or equal to 50 mT.

The imaging device 1 also comprises a set of gradient coils 6. The gradient coils 6 are particularly configured to produce small-amplitude magnetic fields and vary in space when a current is applied thereto.

More particularly, the gradient coils 6 are designed to produce a magnetic field component that is aligned parallel to the static magnetic field, and which varies linearly in amplitude with the position along one of the axes x, y or z (the axes x, y and z form an orthogonal reference frame).

Thus, the combined effects of the magnetic fields imposed by the gradient coils 6 make it possible to spatially encode the signals coming from a body present in the bore 3 and intended to be probed. Spatial encoding is manifested, in particular, by a variation in the resonance energy of the nuclear spins of the hydrogen nuclei in the body intended to be probed and present in the analysis zone. In other words, the nuclear spins of the hydrogen nuclei are subjected to a magnetic field, which differs from one position to another.

The imaging device 1 further comprises a radio frequency assembly 7.

As shown in FIG. 2, the radio frequency assembly 7 comprises a radio frequency coil 8. The radio frequency coil 8 is, in particular, arranged in the bore 3 and delimits, at least in part, the analysis zone. The radio frequency coil 8 is further configured to house the body intended to be probed.

The radio frequency coil 8 may also comprise capacitors, called main segmentation capacitors.

The radio frequency coil 8 is characterized by an intrinsic resonant frequency fi and an intrinsic bandwidth Δfi. These two characteristics make it possible, in this respect, to quantify the quality factor Qi of the radio frequency coil. This quality factor Qi, in particular, corresponds to the ratio of the intrinsic resonant frequency fi to the intrinsic bandwidth Δfi.

The radio frequency assembly 7 according to the present disclosure further comprises a tunable circuit 9.

More particularly, the tunable circuit 9 is associated with the radio frequency coil 8, and is configured to allow the adjustment of the equivalent impedance of the radio frequency assembly in a given impedance range.

It is understood that a tunable circuit, according to the terms of the present disclosure, has a variable impedance as a function of the conditions imposed thereon. For example, and this aspect will appear more clearly in the rest of the disclosure, a tunable circuit may comprise an electronic component whose impedance can be adjusted and/or set.

In particular, the adjustment of the equivalent impedance makes it possible to adjust the resonant frequency, called the adjusted frequency, in a frequency range, called the working range, of the radio frequency assembly 7.

In particular, the extent of the working range is greater than the intrinsic bandwidth extent.

Finally, the imaging device further comprises adjustment means 9A configured to command the tunable circuit to dynamically adjust the equivalent impedance, during the acquisition of an image by the imaging device.

The adjustment means 9A may comprise any digital device capable of implementing a command for the tunable circuit to dynamically adjust the equivalent impedance, during the acquisition of an image by the imaging device.

The implementation of the tunable circuit 9 and adjustment means 9A makes it possible to consider a radio frequency coil, which has a relatively high quality factor, and more particularly associated with a bandwidth much lower than the working range. In this respect, the radio frequency coil 8 may, according to the terms of the present disclosure, have a bandwidth less than 15 kHz, advantageously less than 10 KHz.

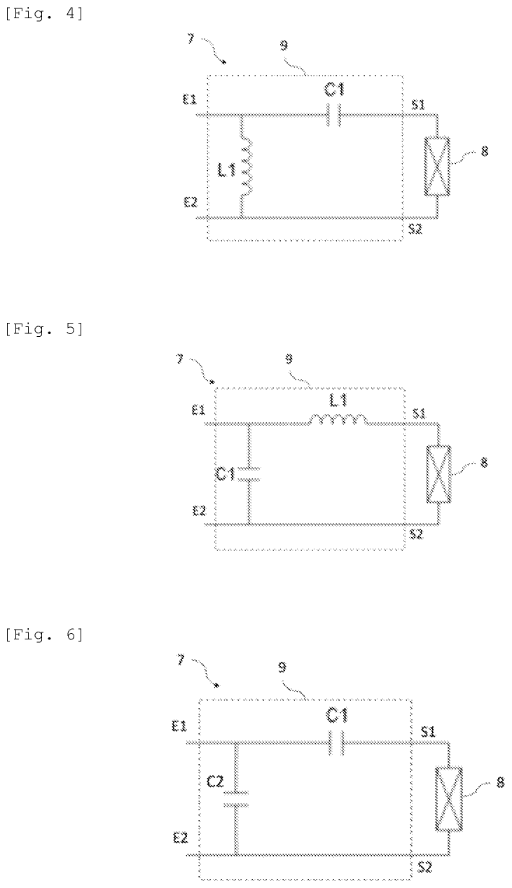

FIG. 3 is a graphic representation of an adjustment of the resonant frequency of the radio frequency assembly 7. In the shown example, the radio frequency coil 8 has an intrinsic bandwidth much lower than the working range, which is approximately 30 kHz. The curves “A,” “B,” “C,” and “D” represent the resonance profiles, at the radio frequency coil, of the radio frequency assembly for four different impedance adjustments of the tunable circuit. More particularly, each of these four profiles has a resonant frequency within the interval defined by the working range. It is understood that continuously varying the impedance of the assembly will make it possible to cover all of the frequencies within the working range.

Thus, and during operation, a body is introduced inside the radio frequency coil 8. This body is then subjected to a field resulting from the sum of the static magnetic field generated by the permanent magnet 2 and the gradient field generated by the gradient coils 6.

The resultant field, variable as a function of the coordinates x, y, and z defined by the reference frame (x, y, z), makes it possible, in particular, to spatially encode the signals coming from each of the positions (x, y, z) of the body intended to be probed, and thereby to impose a resultant field specific to each of these positions. The resultant field at a given position determines in this respect the resonant frequency of the spins of the hydrogen nuclei subjected to the resultant field. In other words, the spatial encoding makes it possible to associate, with each of the positions, a resonant frequency, called natural frequency, of the spins of the hydrogen nuclei at the position. It is understood that the spatial encoding is reflected by a breakdown, in terms of resultant field, into “slices” (perpendicular to the axis z), called working slices, the working slices being themselves broken down into lines, called working lines, parallel to each other and along which the resultant field varies, advantageously in a linear manner. Thus, each working line defines a range of natural frequencies, called the working range, covering all the resonance frequencies of the spins of the hydrogen nuclei belonging to the working line.

During the measurement, the radio frequency assembly 7 is, in particular, adjusted to transmit a radio frequency signal at a given frequency, called the Larmor frequency of the hydrogen cores corresponding to a given working line. This adjustment is then followed by an emission at the Larmor frequency in order to be absorbed for all the hydrogen nuclei of the working line in question.

As soon as the RF transmission is interrupted, the nuclear spins of the working line in question relax in order to return to their initial energy state and in turn emit a RF signal capable of being collected by the radio frequency coil 8. In order to collect all these signals, the adjustment means 9A imposes a dynamic variation of the resonant frequency of the radio frequency assembly in the working range of the working line in question.

This process can then be repeated as many times as necessary to probe each of the working lines.

The radio frequency assembly 7 according to the terms of the present disclosure thus makes it possible to cover a wide frequency range while considering a radio frequency coil, which has a bandwidth lower than the working range in question. In other words, the dynamic adjustment of the resonant frequency makes it possible to consider a radio frequency coil, which has a quality factor greater than that of a coil associated with a much larger bandwidth, and, in particular, comprising the working range.

According to one embodiment, the tunable circuit 9 may comprise at least two components arranged according in an L-shaped topology, and which combined together in the tunable circuit generate a reactance, one and/or the other of these two components being tunable so as to allow the adjustment of the equivalent impedance of the radio frequency assembly.

Advantageously, the two components comprise two capacitors, or two inductors, or one capacitor and one inductor.

The remainder of the disclosure is limited to a tunable circuit formed by a capacitor C1 and an inductor L1. However, the person skilled in the art could adapt the present description to consider a tunable circuit formed either by two inductors, or by two capacitors. By way of example, a person skilled in the art will be able to consider two components each formed by a capacitor C1 and C2 (as illustrated in FIG. 6), or each by an inductor (not shown).

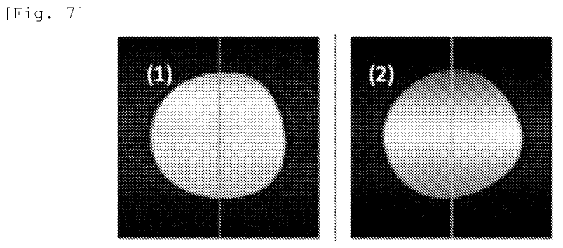

According to a particularly advantageous embodiment, the tunable circuit 9 comprises an inductor L1 and a capacitor C1, and has an L-shaped topology (FIG. 4 and FIG. 5). In particular, the tunable circuit 9 may be formed by an integrated circuit, which comprises the inductor L1 and the capacitor C1.

More particularly, one and/or the other of the inductor L1 and the capacitor C1 is tunable.

Thus, according to a first variant, it is possible to consider a tunable capacitor C1. In other words, the equivalent impedance of the radio frequency assembly can be adjusted by varying the capacitance of the capacitor C1.

According to a second variant, it is possible to consider a tunable inductor L1. In other words, the equivalent impedance of the radio frequency assembly can be adjusted by varying the inductance of the inductor L1.

Still according to this advantageous embodiment, the tunable circuit 9 comprises two inputs and two outputs. In particular, the two inputs called, respectively, first input El and second input E2 are intended to be powered by a generator of current pulses, while the two outputs called, respectively, first output S1 and second output S2, are each connected to one of the ends of the radio frequency coil 8. One and/or the other of the second input E2 and the second output S2 may be grounded.

More particularly, the radio frequency assembly 7 comprises two branches, respectively, first branch and second branch, connected in parallel respectively to the first input E1 and to the second input E2. The first branch comprises, connected in series, the radio frequency coil 8 and either the inductor L1 or the capacitor C1, while the second branch comprises the other of the inductor L1 and the capacitor 1.

More particularly, FIG. 4 shows a radio frequency assembly whose first branch is formed by a serial connection of the radio frequency coil 8 and of the capacitor C1, and a second branch formed by the inductor L1.

Likewise, FIG. 5 shows a radio frequency assembly whose first branch is formed by a serial connection of the radio frequency coil 8 and of the inductor L1, and a second branch formed by the capacitor C1.

The magnetic resonance imaging device may further comprise radio frequency pulse generation means 10, adapted to impose, via the tunable circuit 9, the circulation of a current pulse in the radio frequency coil 8. Advantageously, the pulse generation means 10 for generating radio frequency pulses can also be configured to control the tunable circuit, and consequently allow the adjustment of the equivalent impedance. However, the present disclosure is not limited by this aspect, and a person skilled in the art, on the basis of their general knowledge, may consider any other means, for example, a digital controller, to adjust the equivalent impedance.

The magnetic resonance imaging device may further comprise radio frequency processing means 11 adapted to process a radio frequency signal capable of being received by the radio frequency coil 8.

More particularly, the radio frequency pulse generation means 10 can also be implemented to power the gradient coils 6 in order to spatially encode each of the positions of a body likely to be present in the bore 3.

The imaging device 1 may further comprise an interface 12 providing a link between the pulse generation means 10 and the gradient coils 6.

The adjustment means A The pulse generation means 10, the radio frequency processing means 11, the interface 12 can be controlled by a control unit 13, for example, a computer.

The adjustment means 9A The pulse generation means 10, the radio frequency processing means 11, the interface 12 can be integrated into a control console of the imaging device.

Furthermore, and according to the terms of the present disclosure, the radio frequency coil 8 can be dimensioned to form a receiving bore (for receiving a body, or of a part of a body) with a length of 50 cm and of 27 cm in diameter.

The imaging device according to the present disclosure can advantageously be implemented in a portable imaging system, and, for example, with a mass of less than 100 Kg (in particular, equal to 75 Kg).

FIG. 7 finally illustrates the effect of the quality factor of the radio frequency coil on the image obtained. More particularly, the image (1) and the image (2) are obtained by means of an imaging device comprising a radio frequency coil having, respectively, a standard quality factor and a high quality factor (greater than the standard quality factor). The image (2) reveals an artifact linked to a high quality factor and which results in a spatial variation of the signal-to-noise ratio along the reading axis. This artifact is detrimental to the clinical interpretation of images. The purpose of the present disclosure is to maintain the signal-to-noise ratio across the entire image.

The present disclosure also relates to a method for acquiring an image, via magnetic resonance, of a body by means of the imaging device 1.

The method particularly comprises the following steps:
a) subjecting the body, disposed within the radio frequency coil, to the static magnetic field;
b) imposing on the body a spatial encoding by means of the gradient coils, the gradient coils subjecting the body to a gradient field, which adds to the static magnetic field, to form a resultant field, in order to associate with each of the positions of the body a resonant frequency, called the natural frequency, of the spins of the hydrogen nuclei, all of the natural frequencies extending over the working range;
c) transmitting, by means of the radio frequency coil, a radio frequency signal so as to excite, over all positions of the body subjected to spatial encoding by the gradient coils, the hydrogen nuclei spins,
d) measuring the echoes of hydrogen nuclei spins emitted by at least some of the positions of the body subjected to the spatial encoding by the gradient coils, the measurement comprising a dynamic adjustment of the equivalent impedance of the assembly formed by the tunable circuit and the radio frequency coil.

Advantageously, the spatial encoding may be imposed by the gradient coils is reflected by a breakdown, in terms of the resultant field, into slices called working slices, the working slices themselves being subdivided into mutually parallel working lines, along which the resultant field varies.

More advantageously, the measurement of the spin echoes is carried out one working line at a time.

In particular, the spin echoes likely to be measured along a working line cover a frequency range whose extent is greater than the bandwidth of the radio frequency coil, the measurement along a working line is executed by dynamically adjusting the equivalent impedance of the assembly formed by the tunable circuit and the radio frequency coil so as to collect all the spin echoes associated with the working line.

The frequency range associated with the spin echoes of one line may be of an extent at least 5 times greater, advantageously 10 times greater, than the intrinsic bandwidth of the radio frequency coil.

Step c) can also be executed by considering a dynamic adjustment of the equivalent impedance of the assembly formed by the tunable circuit and the radio frequency coil.

Alternatively, the dynamic adjustment may not be implemented during the execution of step c) so as to collectively export a plurality of regions of the body.

Of course, the present disclosure is not limited to the described embodiments, and variant embodiments may be envisaged without departing from the scope of the invention as defined by the claims.

1. A magnetic resonance imaging device including a radio frequency assembly configured to transmit and receive radio frequency signals, the radio frequency assembly comprising:
a magnet defining a bore;
a radio frequency coil, arranged in the bore, the interior of the radio frequency coil forming an analysis zone, wherein the magnet imposes a static magnetic field, the radio frequency coil being characterized for an intrinsic bandwidth and an intrinsic resonant frequency, and configured to transmit and receive radio frequency signals;
a tunable circuit associated with the radio frequency coil and configured to enable adjustment of an equivalent impedance of the radio frequency assembly within a given impedance range, the adjustment of the equivalent impedance causing adjustment of the resonant frequency from the intrinsic resonant frequency to an adjusted resonant frequency, within a working frequency range of the radio frequency assembly, an extent of the working frequency range being greater than an extent of the intrinsic bandwidth;
adjustment means configured to command the tunable circuit to dynamically adjust the equivalent impedance during an acquisition of an image by the imaging device;
frequency processing means, the radio frequency processing means being adapted to process a radio frequency signal capable of being received by the radio frequency coil; and
gradient coils configured to spatially encode positions of the analysis zone, the spatial encoding, in combination with the static magnetic field, associating each of the positions with a natural resonant frequency to spins of hydrogen nuclei positioned at the respective positions.

2. The magnetic resonance imaging device of claim 1, wherein the adjustment means are configured to allow a radio frequency transmission at a given Larmor frequency and a reception of radio frequency signals during which the adjusted frequency is dynamically tuned in the working frequency range.

3. The magnetic resonance imaging device of claim 1, wherein the radio frequency coil comprises main segmentation capacitors.

4. The magnetic resonance imaging device of claim 1, wherein the tunable circuit comprises at least two components arranged in an L-shaped topology, and which combined together in the tunable circuit generate a reactance, one and/or the other of these two components being tunable so as to allow the adjustment of the equivalent impedance of the radio frequency assembly.

5. The magnetic resonance imaging device of claim 4, wherein the tunable circuit comprises two first inputs and two first outputs, the two first inputs including a first input and a second input configured to be powered by a generator of current pulses, the two first outputs including a first output and a second output, each connected to one of the ends of the radio frequency coil.

6. The magnetic resonance imaging device of claim 5, wherein the radio frequency assembly comprises two branches including a first branch and second branch connected in parallel to the level, respectively, of the first input and of the second input, the first branch comprising, connected in series, the radio frequency coil and one of the two components, the second branch comprising the other of the two components.

7. The magnetic resonance imaging device of claim 1, wherein the radio frequency assembly further comprises radio frequency pulse generating means, the radio frequency pulse generating means being adapted to impose, via the tunable circuit, the circulation of a current pulse in the radio frequency coil.

8. The magnetic resonance imaging device of claim 1, wherein the magnet is a permanent magnet.

9. (canceled)

10. The magnetic resonance imaging device of claim 1, wherein the adjusted frequency can cover, by adjusting the equivalent impedance, all of the natural frequencies of the hydrogen nuclei spins likely to be present on each of the positions of the analysis zone.

11. A method for acquiring a magnetic resonance image, using an imaging device according to claim 1, the method comprising the following steps:
a) subjecting the body, disposed within the radio frequency coil, to the static magnetic field;
b) imposing on the body a spatial encoding by way of the gradient coils, the gradient coils subjecting the body to a gradient field, which adds to the static magnetic field, to form a resultant field, to associate with each of the positions of the body a natural resonant frequency of the spins of the hydrogen nuclei, all of the natural resonant frequencies extending over the working range;
c) transmitting, by way of the radio frequency coil, a radio frequency signal so as to excite, over all positions of the body subjected to spatial encoding by the gradient coils, the hydrogen nuclei spins; and
d) measuring echoes of hydrogen nuclei spins emitted by at least some of the positions of the body subjected to the spatial encoding by the gradient coils, the measurement comprising a dynamic adjustment of the equivalent impedance of the assembly formed by the tunable circuit and the radio frequency coil.

12. The method of claim 11, wherein the spatial encoding imposed by the gradient coils is reflected by a breakdown, in terms of the resultant field, into working slices, the working slices themselves being subdivided into mutually parallel working lines, along which the resultant field varies.

13. The method of claim 12, wherein the measurement of the spin echoes is carried out one working line at a time.

14. The method of claim 13, wherein the spin echoes likely to be measured along a working line cover a frequency range whose extent is greater than the bandwidth of the radio frequency coil, the measurement along a working line is executed by dynamically adjusting the equivalent impedance of the assembly formed by the tunable circuit and the radio frequency coil so as to collect all the spin echoes associated with the working line.

15. The method of claim 14, wherein the frequency range associated with the spin echoes of one line is of an extent at least 5 times greater than the intrinsic bandwidth of the radio frequency coil.

16. The method of claim 15, wherein the frequency range associated with the spin echoes of one line is of an extent at least 10 times greater than the intrinsic bandwidth of the radio frequency coil.

17. The magnetic resonance imaging device of claim 4, wherein the two components comprise two capacitors, or two inductors, or a capacitor and an inductor.

18. The magnetic resonance imaging device of claim 8, wherein the permanent magnet is capable of generating a static magnetic field less than 100 mT.

19. The magnetic resonance imaging device of claim 18, wherein the permanent magnet is capable of generating a static magnetic field less than 50 mT.
